(19) United States
(12) Patent Application Publication
(10) Pub. No.: US 2026/0045439 A1
(43) Pub. Date: Feb. 12, 2026

(54) Shield for an Ion Implanter

(71) Applicant: Applied Materials, Inc., Santa Clara, CA (US)

(72) Inventors: James A. Pixley, Dover, NH (US); Gregory Edward Stratoti, Sandown, NH (US); Santosh Dhulapati, Wakefield, MA (US); Tseh-Jen Hsieh, Rowley, MA (US); Bon-Woong Koo, Andover, MA (US)

(21) Appl. No.: 19/084,403

(22) Filed: Mar. 19, 2025

Related U.S. Application Data
(60) Provisional application No. 63/682,133, filed on Aug. 12, 2024.

(51) Int. Cl. H01J 37/09; H01J 37/20; H01J 37/317

(52) U.S. Cl. CPC H01J 37/09; H01J 37/20; H01J 37/3171; H01J 2237/2007

(57) ABSTRACT

A shield for use with a rotatable platen is disclosed. The shield includes a frame, which is mounted to the base of the platen. The electrostatic chuck is then mounted to the frame. The frame includes a plurality of ribs that extend radially outward from a center portion. The ribs terminate in one or more arc shaped support members, which hold a protective cover. This protective cover surrounds the entirety of the circumference of the electrostatic chuck, protecting it from the incoming ion beam at high tilt angles.

This application claims priority of U.S. Provisional Patent Application Ser. No. 63/682,133, filed Aug. 12, 2024, the disclosure of which is incorporated herein by reference in its entirety.

### FIELD

This disclosure describes embodiments of a shield for use in an ion implanter to protect a platen.

### BACKGROUND

Semiconductor devices are fabricated using a plurality of processes, some of which implant ions into the workpiece. The incoming ion beam typically is very narrow in the height direction, but has a width that is greater than the diameter of the workpiece. This width may be achieved using a ribbon ion beam, or by the scanning of a spot ion beam.

The ion beam typically impacts the workpiece at an angle that is normal to the direction of the ion beam. The workpiece is clamped to and supported by a platen. However, in certain embodiments, it may be useful to perform the implant at an angle that is not normal to the ion beam. This may be referred to as an angled implant or a tilted implant.

When the workpiece is tilted, it is possible that the ion beam may strike the platen. Therefore, in certain situations, a shield may be disposed around the platen to protect the platen from this ion beam strike. Thus, the purpose of the shield is to be impacted by the ion beam so that the platen is not damaged by the ion beam. However, as tilt angles become higher, protecting the platen is becoming a higher priority.

Therefore, it would be beneficial if there were a shield that protected the platen, even at high tilt angles. High tilt angles may be angles greater than 50°, such as between 60° and 90°.

### SUMMARY

A shield for use with a rotatable platen is disclosed. The shield includes a frame, which is mounted to the base of the platen. The electrostatic chuck is then mounted to the frame. The frame includes a plurality of ribs that extend radially outward from a center portion. The ribs terminate in one or more arc shaped support members, which hold a protective cover. This protective cover surrounds the entirety of the circumference of the electrostatic chuck, protecting it from the incoming ion beam at high tilt angles.

According to one embodiment, an ion implanter is disclosed. The ion implanter comprises an ion source to generate an ion beam; a platen to support a workpiece that is treated with the ion beam, the platen positioned within a process chamber of the ion implanter and comprising a base and an electrostatic chuck; and a shield to protect the electrostatic chuck from the ion beam; wherein the shield comprises a frame that is mounted to the base and wherein the electrostatic chuck is mounted to the frame; and wherein the shield comprises a protective cover that surrounds an entirety of a circumference of the electrostatic chuck. In some embodiments, a gap between the protective cover and the electrostatic chuck is less than 0.5 mm. In some embodiments, the protective cover is made from graphite. In some embodiments, the frame comprises a center portion mounted to the base. In some embodiments, the center portion comprises openings to allow power signals and conduits to pass from the base to the electrostatic chuck. In certain embodiments, the frame further comprises one or more arc shaped support members, wherein the protective cover is mounted to the one or more arc shaped support members. In certain embodiments, the frame further comprises ribs extending radially outward from the center portion to the one or more arc shaped support members. In some embodiments, a plurality of openings are formed by adjacent pairs of ribs, and inserts are disposed in the plurality of openings. In certain embodiments, the inserts are made from graphite, silicon, aluminum, silicon carbide, boron, boron carbide, or nickel.

According to another embodiment, a shield for use with a platen is disclosed. The shield comprises a frame, comprising: a center portion adapted to be mounted to a base of the platen; and one or more arc shaped support members attached to the center portion; and a protective cover mounted to the one or more arc shaped support members. In some embodiments, the protective cover is graphite. In some embodiments, the center portion comprises retaining holes to allow a first set of fasteners to affix a bottom surface of the center portion to the base; and mounting holes to allow a second set of fasteners to affix an electrostatic chuck to a top surface of the center portion. In some embodiments, the frame further comprises ribs extending outward from the center portion to the arc shaped support members to attach the arc shaped support members to the center portion. In certain embodiments, inserts are disposed in each of a plurality of openings, each opening defined by the protective cover, two adjacent ribs and the center portion. In certain embodiments, the inserts are graphite, silicon, aluminum, silicon carbide, boron, boron carbide or nickel. In some embodiments, a radius of the one or more arc shaped support members is at least twice a radius of the center portion. In some embodiments, the one or more arc shaped support members do not support an entirety of the protective cover. In some embodiments, the one or more arc shaped support members comprises one support member formed as a ring. In some certain embodiments, an attachment between the center portion and the ring comprises a solid material, made of a same material as the center portion. In some embodiments, the frame is aluminum.

### BRIEF DESCRIPTION OF THE DRAWINGS

For a better understanding of the present disclosure, reference is made to the accompanying drawings, in which like elements are referenced with like numerals, and in which:

FIG. 1 is a block diagram of an ion implanter that uses the shield according to one embodiment;

FIG. 2 is a block diagram of a process chamber with a platen and shield;

FIG. 3 shows rotation and tilt of a workpiece on the platen;

FIG. 4 shows the process chamber with the electrostatic chuck at a high X-tilt angle;

FIG. 5 shows the frame of the shield;

FIG. 6 shows the shield mounted to the base of the platen;

FIG. 7 shows the shield mounted to the base with the electrostatic chuck installed;

FIG. 8 shows a cross-sectional view of the frame, the protective cover and the electrostatic chuck according to one embodiment;

FIG. 9 shows a front view of the shield covering the electrostatic chuck according to one embodiment; and

FIG. 10 shows inserts disposed in the openings in the frame.

### DETAILED DESCRIPTION

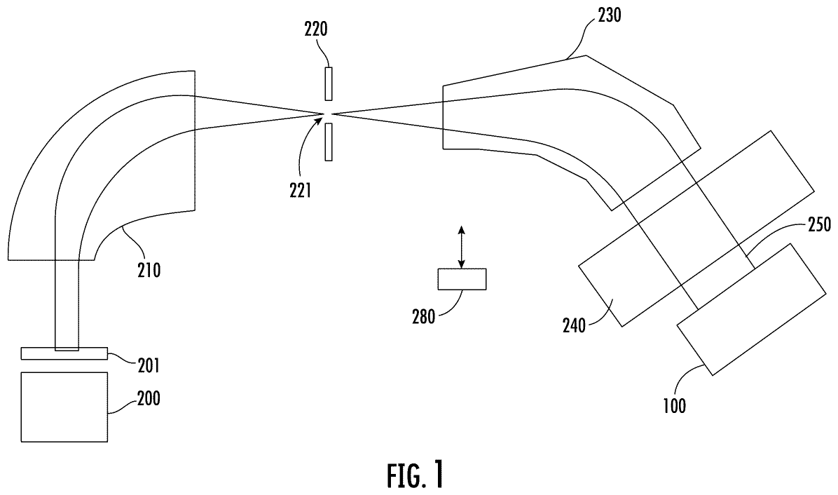

FIG. 1 shows an ion implanter that includes a process chamber 100 that contains a platen and a shield. An ion source 200 is used to generate an ion beam 250. The ion source 200 may be a an indirectly heated cathode (IHC) ion source. Alternatively, the ion source 200 may be a capacitively coupled plasma source, an inductively coupled plasma source, a Bernas source or another source. Thus, the type of ion source is not limited by this disclosure. Disposed outside and proximate the extraction aperture of the ion source 200 is the extraction optics 201, which may comprise one or more electrodes.

Located downstream from the extraction optics 201 is a mass analyzer 210. The mass analyzer 210 uses magnetic fields to guide the path of the extracted ion beam. The magnetic fields affect the flight path of ions according to their mass and charge. A mass resolving device 220 that has a resolving aperture 221 is disposed at the output, or distal end, of the mass analyzer 210. By proper selection of the magnetic fields, only those ions in the ion beam 250 that have a selected mass and charge will be directed through the resolving aperture 221. Other ions will strike the mass resolving device 220 or a wall of the mass analyzer 210 and will not travel any further in the system.

A collimator 230 may be disposed downstream from the mass resolving device 220. The collimator 230 accepts the ions from the ion beam 250 that pass through the resolving aperture 221 and creates an ion beam formed of a plurality of parallel or nearly parallel beamlets. The output, or distal end, of the mass analyzer 210 and the input, or proximal end, of the collimator 230 may be a fixed distance apart. The mass resolving device 220 is disposed in the space between these two components.

Located downstream from the collimator 230 may be an acceleration/deceleration stage 240. The acceleration/deceleration stage 240 is a beam-line lens component configured to independently control deflection, deceleration, and focus of the ion beam. For example, the acceleration/deceleration stage 240 may be an electrostatic filter (EF). The ion beam 250 that exits the acceleration/deceleration stage 240 enters the process chamber 100.

A controller 280 may be in communication with one or more of the power supplies such that the voltage or current supplied by these power supplies may be monitored and/or modified. The controller 280 may include a processing unit, such as a microcontroller, a personal computer, a special purpose controller, or another suitable processing unit. The controller 280 may also include a non-transitory storage element, such as a semiconductor memory, a magnetic memory, or another suitable memory. This non-transitory storage element may contain instructions and other data that allows the controller 280 to perform the functions described herein.

In certain embodiments, the ion source 200 may generate a ribbon beam that travels through these components. Thus, while FIG. 1 shows a ribbon beam system, it is understood that the ion implantation system may utilize a scanned beam. Such an ion implanter includes an ion source that creates a spot beam. This type of ion implanter also includes a mass analyzer and a mass resolving device, as described above. In addition, a scanner, which may be electrostatic or another type is used to create a scanned ion beam. Specifically, the beam may enter an electrostatic scanner, which is used to scan a spot beam in the width direction so as to form the scanned ion beam, which is in the form of a ribbon ion beam, having a width much larger than its height. The scanned ion beam may then pass through an angle corrector. The angle corrector is designed to deflect ions in the scanned ion beam to produce an ion beam having parallel ion trajectories, thus focusing the scanned ion beam. Specifically, the angle corrector is used to alter the diverging ion trajectory paths into substantially parallel paths of the ion beam 250. In some embodiments, the angle corrector may comprise magnetic pole pieces which are spaced apart to define a gap and a magnet coil which is coupled to a power supply. The scanned ion beam passes through the gap between the magnetic pole pieces and is deflected in accordance with the magnetic field in the gap. In other embodiments, the angle corrector may be an electrostatic lens, sometimes referred to as a parallelizing lens.

The ion beam 250 travels in the Z direction and has a larger dimension in the X direction and a smaller dimension in the Y direction. The X direction may be referred to as the width of the ion beam while the Y direction may be referred to as the height of the ion beam. The X direction and Y direction are perpendicular to one another.

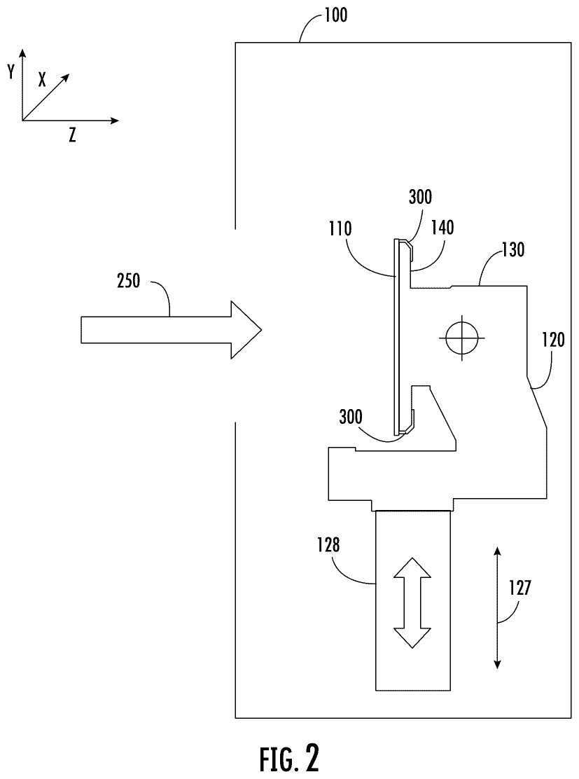

FIG. 2 shows the process chamber 100 of FIG. 1 in more detail. The process chamber 100 includes a platen 120, on which a workpiece 110 may be disposed. When in the operational position, the ion beam 250 impacts the workpiece 110. The platen 120 may include an electrostatic chuck 140 that is used to clamp and hold the workpiece 110 while the ion beam 250 is directed into the process chamber 100. In some embodiments, the platen 120 may be elevated and lowered in a Y direction 127 through the movement of shaft 128.

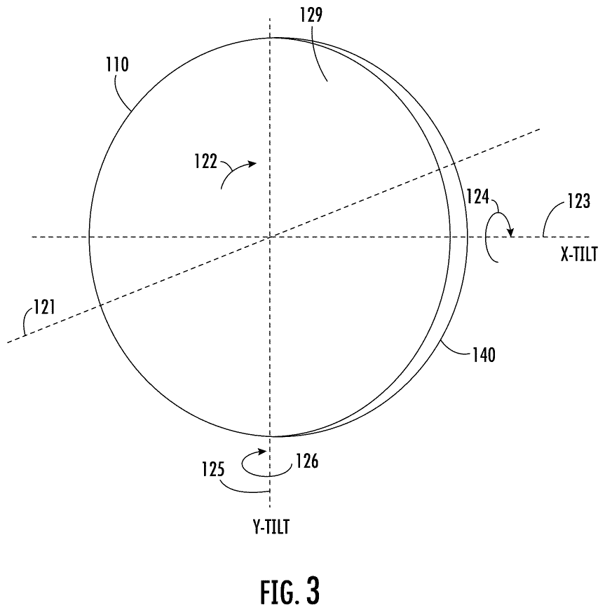

Additionally, the platen 120 may rotate about different axis. FIG. 3 shows the platen 120 and its various directions of rotation. FIG. 3 shows a perspective view of the platen 120 that is capable of rotation, referred to as a roplat. As seen in FIG. 2, the roplat includes a base 130 and an electrostatic chuck 140. The electrostatic chuck 140 is mounted above the top surface of the base 130. The electrostatic chuck 140 includes one or more electrodes that enable the electrostatic chuck to generate an electrostatic force that clamps the workpiece 110 to the clamping surface 129. The electrostatic chuck 140 is rotatably coupled to the base 130. The platen 120 may have three axes. There may be a twist axis 121, which is perpendicular to the clamping surface 129 of the electrostatic chuck 140 and passes through the center of the electrostatic chuck 140. Rotation about this twist axis 121 is referred to as a twist angle 122. Note that the electrostatic chuck 140 is rotatable about the twist axis 121, while the base 130 remains fixed. There is an X axis 123 that passes through the platen 120, is parallel to the clamping surface 129 of the platen 120 and is perpendicular to the twist axis 121. The X axis 123 is parallel to the wide dimension of the ion beam 250. Tilting about the X axis 123 is referred to as an X-tilt angle 124 and is achieved by rotation of the electrostatic chuck 140 on the base 130. X-tilt angles are measured with respect to the vertical direction. In other words, when the clamping surface 129 is vertical, as shown in FIG. 2, the X-tilt angle is defined as 0°. An X-tilt angle of 90° is defined as being in the horizontal position. As noted above, X-tilt angles greater than 50°, such as between 60° and 90°, may be referred to as high tilt angles. There is also a Y axis 125 that also passes through the platen 120, is parallel to the clamping surface 129 of the platen 120 and is perpendicular to the twist axis 121 and the X axis 123. The Y axis 125 is parallel to the narrow dimension of the ion beam 250. Tilting about the Y axis 125 is referred to as a Y-tilt angle 126 and may be achieved by movement of the base 130. For example, the Y-tilt angle 126 may be achieved by rotation of shaft 128.

In certain embodiments, the electrostatic chuck 140 may be rotated 90° about the X axis 123, so that the clamping surface 129 of the electrostatic chuck 140 is horizontal, allowing a workpiece 110 to be placed on the platen 120. This may be referred to as the loading position. The electrostatic chuck 140 is then rotated about the X axis 123 into the operational, or implant position, which is shown in FIG. 2.

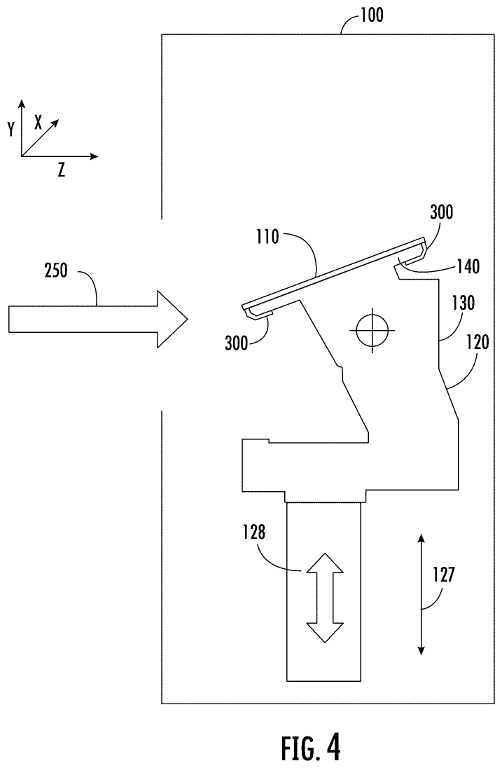

Note that, as shown in FIG. 4, when the electrostatic chuck 140 is tilted about the X axis 123 at a high tilt angle, the bottom portion of the electrostatic chuck 140 may be exposed to the incoming ion beam 250. Thus, to protect the electrostatic chuck 140, a shield 300 may be added.

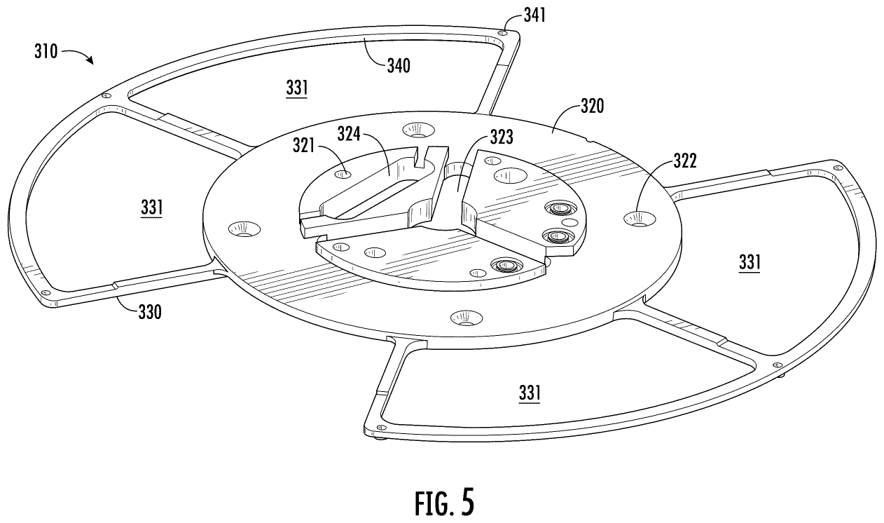

The shield 300 may be made up of two components, a frame 310 and a protective cover 390. FIG. 5 shows a view of the frame 310. The frame 310 may be a unitary component and may be made of a lightweight material, such as aluminum. The frame 310 is adapted to be mounted onto the top surface of the base 130. The frame 310 includes a center portion 320, that is adapted to be fastened to the base 130. The center portion 320 includes a plurality of retaining holes 321, each of which is adapted to retain a screw or other fastener that attaches the frame 310 to the base 130. The center portion 320 also includes a plurality of mounting holes 322 that are adapted to hold fasteners that affix the electrostatic chuck 140 to the center portion 320 of the frame 310. Since the frame 310 is mounted to the electrostatic chuck 140, it will tilt and twist with the electrostatic chuck 140. The center portion 320 also includes a plurality of openings 323. These openings 323 allow communication between the base 130 and the electrostatic chuck 140. For example, fluid lines and other conduits may pass from the base 130 through these openings 323 to the electrostatic chuck 140. Additionally, there may be additional openings 324 that are used to allow the passage of electrical signals from the base 130 to the electrostatic chuck 140.

Extending radially outward from the center portion 320 are a plurality of ribs 330. While FIG. 5 shows six ribs 330, it is understood that a different number of ribs 330 may be utilized. The ribs 330 terminate in one or more arc shaped support members 340. The arc shaped support members 340 have a radius that is roughly equal to that of the electrostatic chuck 140. While FIG. 5 shows two arc shaped support members 340, it is understood that more arc shaped support members may be used. For example, an arc shaped support member may connect two adjacent ribs 330. Thus, if there were six ribs, there may be 3 arc shaped support members. Note that in these embodiments, the arc shaped support members 340 do not support the entirety of the protective cover 390. In some embodiments, this may be done to reduce the weight of the shield 300. Furthermore, in other embodiments, the arc shaped support member 340 may be a single ring, surrounding the entirety of the center portion 320. In embodiments with ribs 330, there are openings 331 located between each pair of adjacent ribs. In certain embodiments, each opening 331 is defined as the area bounded by two ribs 330, the center portion 320 and the protective cover 390. The arc shaped support members 340 may each include one or more holes 341. The holes 341 are used to affix the protective cover 390 to the arc shaped support members 340. For example, a screw or other fastener may pass through the hole 341 and secure the protective cover 390 to the arc shaped support member 340. Note that in certain embodiments, the radius of the center portion 320 may be less than or equal to half of the radius of the arc shaped support members 340.

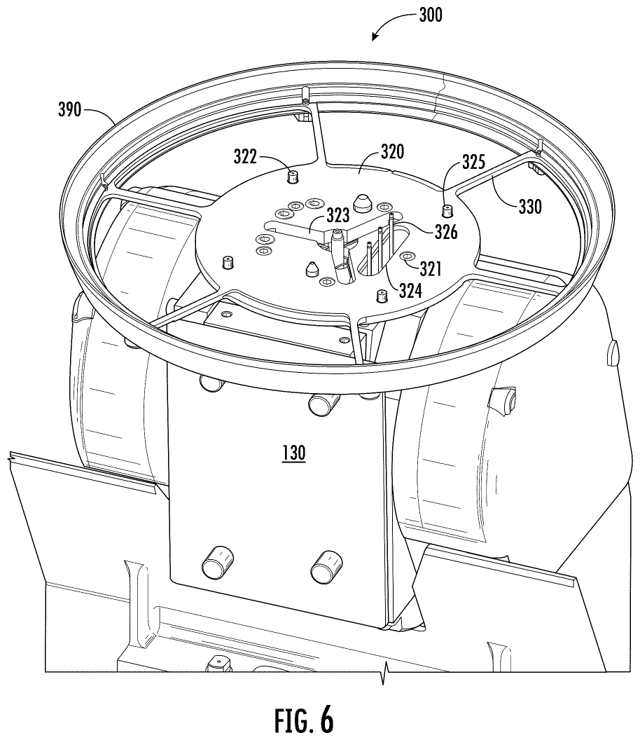

FIG. 6 shows the shield 300 mounted to the base 130. As described above, the center portion 320 is mounted to the top surface of the base 130 by passing fasteners through retaining holes 321. The electrostatic chuck 140 is attached to the center portion 320 through the use of fasteners 325 passing through mounting holes 322. Further, as shown in FIG. 6, the connections from the base 130 to the electrostatic chuck 140, such as fluid lines and other conduits, pass through the openings 323. The base 130 may include spring loaded pins 326 which pass through opening 324 and contact the underside of the electrostatic chuck 140 to supply electrical signals.

While FIGS. 5-6 show a plurality of ribs 330 that link the center portion 320 to the arc shaped support members 340, other embodiments are also possible. For example, in another embodiment, the connection between the center portion 320 and the arc shaped support members 340 may be a solid material, such that the entirety of the frame 310 is circular. Thus, in this embodiment, the openings 331 between the ribs 330 is no longer present and are replaced by a solid material, which is the same material as used for the center portion 320.

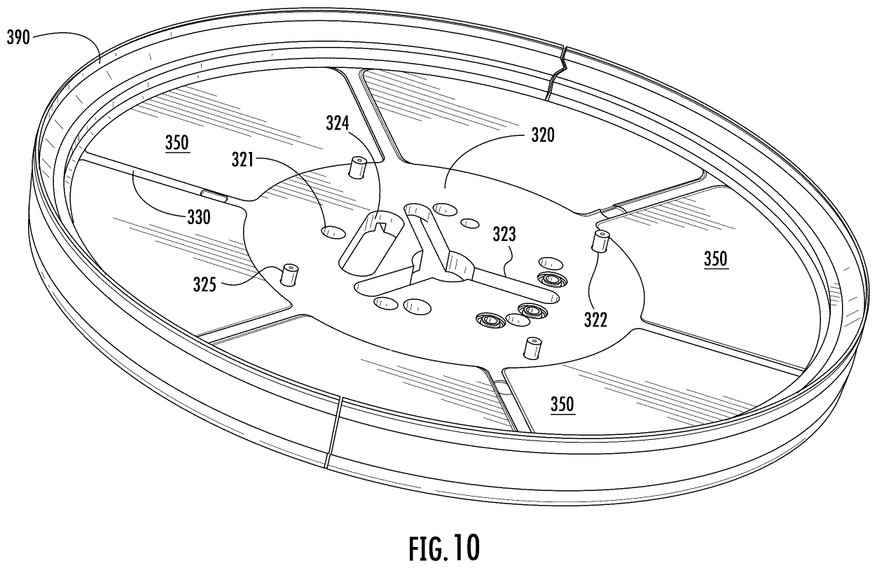

In yet another embodiment, inserts may be placed in each of the openings 331. This may be seen in FIG. 10. The inserts 350 are placed between adjacent ribs 330. These inserts 350 may fill the entire opening. In certain embodiments, the inserts 350 are press fit between the adjacent ribs 330, the center portion 320 and the arc shaped support members 340. In other embodiments, these inserts 350 may be fastened in place, such as by the use of screws that pass through the center portion 320, the ribs 330, the protective cover 390, and/or the arc shaped support members 340. In some embodiments, these inserts 350 may be made of graphite, although other materials may also be used, such as aluminum, silicon, silicon carbide, boron, boron carbide, nickel and others. These inserts 350 may prevent the bottom of the electrostatic chuck 140 from being exposed to the ion beam 250.

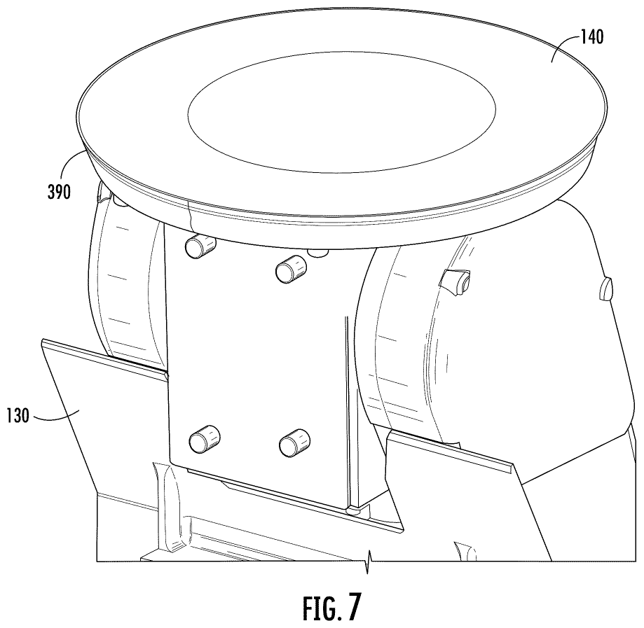

FIG. 7 shows the shield 300 and the electrostatic chuck 140 mounted to the base 130. Note that the protective cover 390 surrounds the entirety of the circumference of the electrostatic chuck 140, such that even if a high tilt angle is used, the electrostatic chuck 140 is protected from the incoming ion beam 250. This protective cover 390 may be graphite, although it is understood that other materials, such as single crystal silicon, silicon carbide, nickel, yttrium, zirconium, and doped diamond-like carbon (DLC) may also be used.

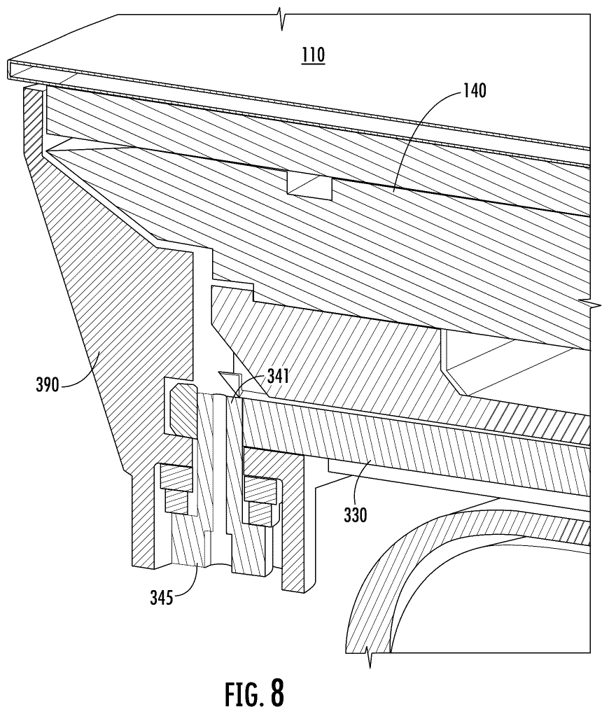

FIG. 8 shows a cross-section of the shield 300 and the electrostatic chuck 140. Note that a fastener 345 passes through the holes 341 in the arc shaped support member 340 to secure the protective cover 390 to the frame 310. The protective cover 390 shields the arc shaped support members 340 and the electrostatic chuck 140 from the incoming ion beam 250. In some embodiments, the thickness of the protective cover 390 near its top surface may be between about 0.5 mm and 1 mm thick, although other dimensions are possible. The overall height of the protective shield is such that the entirety of the thickness of the electrostatic chuck 140 is covered, and may be between about 35 and 50 mm in some embodiments.

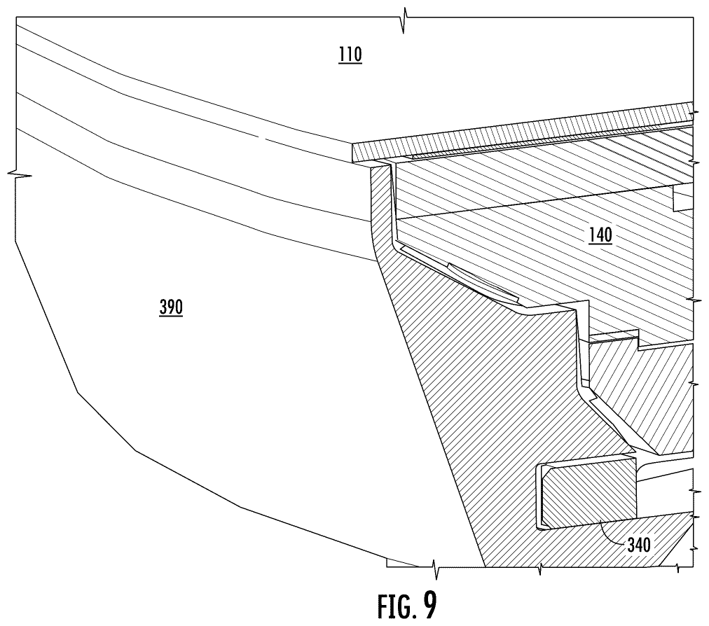

The present system has many advantages. FIG. 4 shows a perspective view of the shield 300 and the electrostatic chuck 140 when disposed at a high tilt angle. Note that the electrostatic chuck 140 is vulnerable to beam strike at this high tilt angle, and consequently a shield 300 is used. Further, the shield 300 is designed to remain very close to the electrostatic chuck 140 through all rotations and tilts. Because the electrostatic chuck 140 is mounted to the frame 310, using fasteners 325 passing through mounting holes 322, the shield 300 may be designed to create a very small gap between the shield 300 and the workpiece 110 mounted on the electrostatic chuck 140, such as less than 0.5 mm, as seen in FIG. 9. Further, the height of the protective cover 290 may be such that the entire thickness of the electrostatic chuck 140 is covered by the protective cover 390. In this way, the electrostatic chuck 140 may be protected. This helps reduce the possibility of damage to the electrostatic chuck 140 during high tilt angle implants.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An ion implanter, comprising;
an ion source to generate an ion beam;
a platen to support a workpiece that is treated with the ion beam, the platen positioned within a process chamber of the ion implanter and comprising a base and an electrostatic chuck; and
a shield to protect the electrostatic chuck from the ion beam;
wherein the shield comprises a frame that is mounted to the base and wherein the electrostatic chuck is mounted to the frame; and wherein the shield comprises a protective cover that surrounds an entirety of a circumference of the electrostatic chuck.

2. The ion implanter of claim 1, wherein a gap between the protective cover and the electrostatic chuck is less than 0.5 mm.

3. The ion implanter of claim 1, wherein the protective cover is made from graphite.

4. The ion implanter of claim 1, wherein the frame comprises a center portion mounted to the base.

5. The ion implanter of claim 4, wherein the center portion comprises openings to allow power signals and conduits to pass from the base to the electrostatic chuck.

6. The ion implanter of claim 4, wherein the frame further comprises one or more arc shaped support members, wherein the protective cover is mounted to the one or more arc shaped support members.

7. The ion implanter of claim 6, wherein the frame further comprises ribs extending radially outward from the center portion to the one or more arc shaped support members.

8. The ion implanter of claim 7, wherein a plurality of openings are formed by adjacent pairs of ribs, and further comprising inserts disposed in the plurality of openings.

9. The ion implanter of claim 8, wherein the inserts are made from graphite, silicon, aluminum, silicon carbide, boron, boron carbide, or nickel.

10. A shield for use with a platen, comprising:
a frame, comprising:
a center portion adapted to be mounted to a base of the platen; and
one or more arc shaped support members attached to the center portion; and
a protective cover mounted to the one or more arc shaped support members.

11. The shield of claim 10, wherein the protective cover is graphite.

12. The shield of claim 10, wherein the center portion comprises retaining holes to allow a first set of fasteners to affix a bottom surface of the center portion to the base; and mounting holes to allow a second set of fasteners to affix an electrostatic chuck to a top surface of the center portion.

13. The shield of claim 10, wherein the frame further comprises ribs extending outward from the center portion to the arc shaped support members to attach the arc shaped support members to the center portion.

14. The shield of claim 13, further comprising inserts disposed in each of a plurality of openings, each opening defined by the protective cover, two adjacent ribs and the center portion.

15. The shield of claim 14, wherein the inserts are graphite, silicon, aluminum, silicon carbide, boron, boron carbide or nickel.

16. The shield of claim 10, wherein a radius of the one or more arc shaped support members is at least twice a radius of the center portion.

17. The shield of claim 10, wherein the one or more arc shaped support members do not support an entirety of the protective cover.

18. The shield of claim 10, wherein the one or more arc shaped support members comprises one support member formed as a ring.

19. The shield of claim 18, wherein an attachment between the center portion and the ring comprises a solid material, made of a same material as the center portion.

20. The shield of claim 10, wherein the frame is aluminum.
